(19) United States
(12) Patent Application Publication
(10) Pub. No.: US 2024/0412972 A1
(43) Pub. Date: Dec. 12, 2024

(54) METHOD FOR WAFER TREATMENT

(71) Applicant: Hua Hsu Silicon Materials Co., Ltd., Taichung City (TW)

(72) Inventors: Chiao-Yang Cheng, Taichung City (TW); Hsiang-Yi Liu, Taichung City (TW); Thi-Yen Thu Le, Taichung City (TW)

(73) Assignee: Hua Hsu Silicon Materials Co., Ltd., Taichung City (TW)

(21) Appl. No.: 18/206,110

(22) Filed: Jun. 6, 2023

(51) Int. Cl. H01L 21/02; C30B 25/18; H01L 21/268

(52) U.S. Cl. CPC H01L 21/02694; C30B 25/186; H01L 21/268

(57) ABSTRACT

A method for a wafer treatment includes providing a wafer including a main surface, a surface layer and a base layer; and performing at least one laser process to irradiate the whole surface layer with laser to thereby generate a plurality of defect regions in the surface layer, and the defect regions form at least one array of defect regions.

### BACKGROUND OF THE INVENTION

### 1. Field of the Invention

The present invention relates to a method for a wafer treatment, particularly to a method for processing the interior of a wafer.

### 2. Description of the Prior Art

In semiconductor manufacturing processes, it is common to perform an epitaxial process to form an epitaxial layer on a wafer. The epitaxial layer can be a semiconductor layer, which may include a stress-buffer layer, a high-resistance layer, a carrier transport layer, and/or a cap layer, but is not limited to these. Then, appropriate semiconductor processes, such as thin film deposition, etching, patterning, doping or other processes, are performed to form semiconductor devices. However, for heteroepitaxy or homoepitaxy with doping concentrations differing by more than two orders of magnitude, significant stress is usually generated at the interface between the wafer and the epitaxial layer after the epitaxial process is completed. This stress is usually caused by a lattice constant mismatch or a coefficient of thermal expansion (CTE) mismatch between the wafer and the epitaxial layer.

For example, in the case of forming a gallium nitride epitaxial layer on a silicon wafer using an epitaxial process, the lattice mismatch between silicon and gallium nitride is 17%, and the thermal expansion coefficient mismatch is 54%. This causes the surface of the silicon wafer to warp and thus generates stress, lattice defects, or cracks in the epitaxial layer. These defects and stress not only cause significant warping and brittle characteristics in the wafer after the epitaxial growth, but also lead to difficulties in subsequent device processing. At the same time, they also affect the electron mobility, breakdown or other voltage, electrical performance of subsequent semiconductor devices, thereby reducing their reliability.

In order to solve the aforementioned problem, a buffer epitaxial layer with a superlattice structure or a lattice constant gradient structure can be disposed between the wafer and the epitaxial layer. However, this approach increases the complexity of the manufacturing process. On the other hand, materials that can simultaneously match both the wafer and the epitaxial layer are too limited, which in turn reduces the flexibility of the manufacturing process. Therefore, there is a need in the industry for a method that can release the stress between the wafer and the epitaxial layer.

### SUMMARY OF THE INVENTION

To achieve the above objectives, the present invention provides a method for a wafer treatment, which includes providing a wafer that has a main surface, a surface layer, and a base layer, where the surface layer is located between the main surface and the base layer; and performing at least one laser process to fully irradiate the surface layer with the laser, thereby generating multiple defect regions in the surface layer, and these defect regions constitutes at least one array of defect regions. The defect regions disclosed in the present invention may be single crystals of the material the same as that of the base layer but with different lattice constant, or the defect regions may have polycrystalline structures, amorphous structures, micro bubbles, vaporized regions, or cavities, and can constitute an array of defect regions.

The array of defect regions formed by the method for the wafer treatment of the present invention can effectively absorb the stress of the epitaxial layer subsequently formed on the wafer, and has the advantages of simple steps and low cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic perspective view of a first laser process according to an embodiment of the present invention.

FIG. 2 is a schematic perspective view of a laser process according to an embodiment of the present invention.

FIG. 3 is a schematic cross-sectional view of a first laser process according to an embodiment of the present invention.

FIG. 4 is a schematic cross-sectional view of an embodiment of the present invention after the first laser process.

FIG. 5 is a schematic cross-sectional view of another embodiment of the present invention after the first laser process.

FIG. 6 is a schematic cross-sectional view of another embodiment of the present invention after the first laser process.

FIG. 7 is a perspective view of a first laser process and a second laser process according to an embodiment of the present invention.

FIG. 8 is a schematic cross-sectional view of an embodiment of the present invention after performing the first laser process and the second laser process.

FIG. 9 is a schematic top view of an array of defect regions according to an embodiment of the present invention.

FIG. 10 is a top view of a laser scanning path for performing a laser process according to different embodiments of the present invention.

FIG. 11 is a flowchart of the method for a wafer treatment of the present invention.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. Although the disclosure is described with respect to specific embodiments, the principles of the disclosure, as defined by the claims appended herein, can obviously be applied beyond the specifically described embodiments of the disclosure described herein.

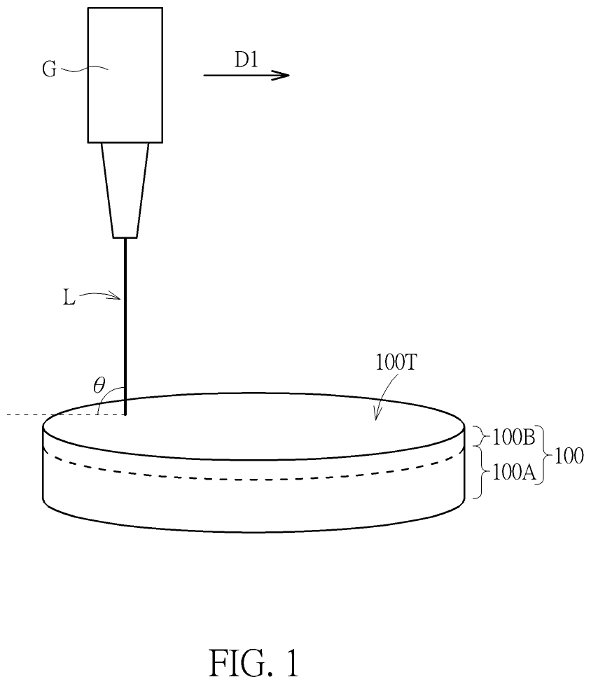

FIG. 1 shows a schematic diagram of a first laser process according to an embodiment of the present invention. A wafer 100 includes a main surface 100T, a surface layer 100B, and a base layer 100A. The surface layer 100B is located between the main surface 100T and the base layer 100A. The material of the wafer 100 may be a single crystal substrate composed of one or more elements, such as silicon, silicon carbide, gallium nitride, aluminum nitride, gallium arsenide, indium phosphide, sapphire, or a composite single crystal wafer composed of a stack of the above-mentioned materials. However, this is not limited thereto. On the other hand, according to different requirements, the wafer 100 can be doped with dopants of different concentrations. The dopants may be group IIIA or VA elements, and the doping concentration may range from 10E16 atoms/cm³ to 10E18 atoms/cm³, but this is not limited thereto. Depending on the rigidity characteristic of the material of the wafer 100, the thickness of the wafer 100 may range from 0.3 mm to 1.5 mm. The thickness of the surface layer 100B in this document will be determined based on the material of the major portion, doping concentration or the thickness of an epitaxial layer subsequently formed on the main surface 100T. For example, when the difference in lattice constants and thermal expansion coefficients between the wafer 100 and the epitaxial layer formed thereon is greater, or the difference in doping concentration between the two is greater, the lattice mismatch become more severe, which causes the surface layer 100B to have the greater. In an embodiment, the thickness of the surface layer 100B may range from 50 μm to 500 μm. It should be noted that the surface layer 100B of the wafer 100 is essentially a homogeneous structure before the laser process is performed, that is, each region of the surface layer 100B has substantially the same lattice constant, crystal plane, crystal structure, and/or doping concentration.

In a first laser process according to this embodiment, multiple paths parallel to the first direction D1 are used to perform the first laser process on the entire surface layer 100B. For example, a laser L is generated by a laser generating device G, and the laser L is irradiated onto the surface layer 100B of the wafer 100 to form multiple first defect regions (not shown) in the surface layer 100B. Multiple first defect regions form a first array of defect regions (not shown).

It should be noted that the defect regions (including first defect regions, second defect regions, third defect regions, or any other defect regions) described herein represents that the defect density, void quantity, grain boundary quantity, and/or crystal structure within that region are different from those in other regions of the surface layer 100B.

It should be noted that irradiating the laser on a certain layer as described herein means that the focal point of the laser is within that layer. For example, when the laser L is irradiated on the surface layer 100B, it means that the focal point of the laser L emitted by the laser generating device G is within the surface layer 100B.

It should be noted that the laser process performed in the present invention is for forming an array of defect regions inside the wafer 100 (e.g., the surface layer 100B). Therefore, the laser wavelength used in the laser process requirements to have the characteristics of penetrating or partially penetrating the wafer so that the energy of the laser will not be significantly absorbed or reflected by the wafer before reaching the predetermined depth.

For example, when the wafer material is silicon, the laser wavelength of the performed laser process needs to be greater than 1300 nm.

In FIG. 1, the laser L, with respect to the main surface 100T of the wafer 100, has a laser incident angle θ1. In one embodiment, the laser incident angle of the first laser process can be 30° to 90°.

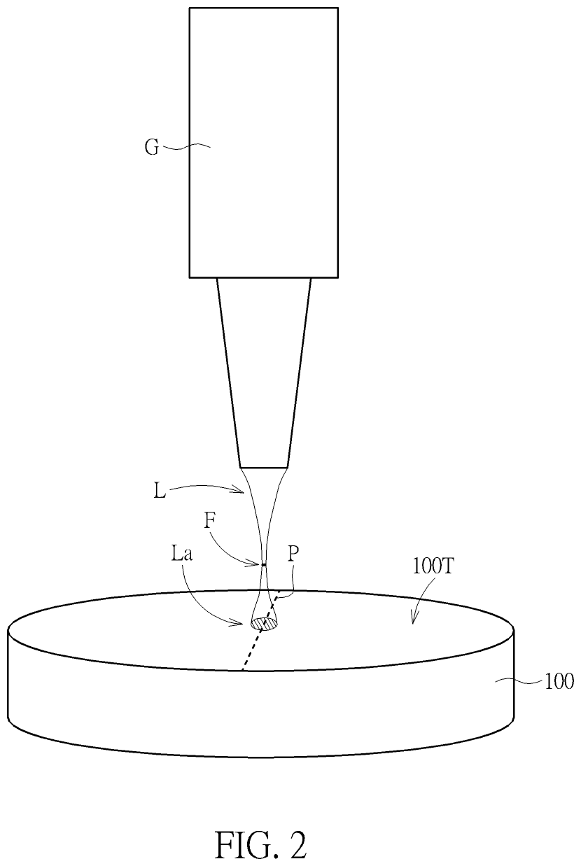

FIG. 2 shows a schematic perspective view of a laser process in an embodiment of the present invention, which further enlarges the laser L emitted by the laser generation device G. The laser generation device G can perform the laser process along a scanning path P and other scanning paths. The laser L emitted by the laser generation device G has a focal point F, and the laser L has a spot La on the outermost exposed surface (e.g., the main surface 100T) of the wafer 100. It should be noted that although the focal point F of the laser L in FIG. 2 is above the outermost exposed surface of the wafer 100, when the focal point F of the laser L is below the outermost exposed surface (e.g., the main surface 100T), there is still a spot La on the outermost exposed surface of the wafer 100.

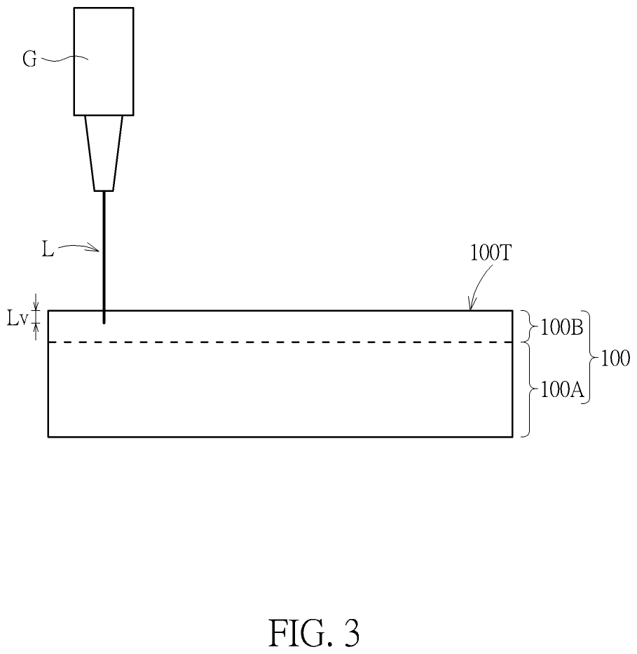

FIG. 3 illustrates a schematic cross-sectional view of a first laser process in an embodiment of the present invention, where a focal offset distance Lv of the first laser process can be located 0.01 μm to 50 μm below the main surface 100T. In one embodiment, the pulse frequency of the first laser process is 1 kHz to 2 MHZ, or 10 KHz to 100 kHz, but is not limited thereto. Depending on different requirements, the pulse frequency can be adjusted according to the material type and the lateral size of the defect regions. The pulse width can be 100 femtoseconds (fs) to 500 nanoseconds (ns), or 0.2 nanoseconds (i.e., 200 picoseconds) to 10 nanoseconds, but is not limited thereto. When the pulse width of the laser is shorter, such as 300 picoseconds (ps), it can be used with a higher pulse frequency, such as MHz or above. The pulse energy of the first laser process can be 600 μJ/pulse to 20 μJ/pulse. It should be noted that the term “pulse energy” in this invention refers to the energy transmitted by the laser during each pulse. The energy received by the irradiated surface of the wafer per unit of time is not only related to the pulse energy but also to the pulse width and pulse frequency. Specifically, the energy received by the irradiated surface of the wafer per unit of time (μJ/ns) can be obtained by dividing the pulse energy by the pulse width. For a laser device with a given power, increasing the pulse frequency will result in a decrease in pulse energy. Additionally, if the laser pulse width is adjusted from the nanosecond level to the picosecond or femtosecond level, the laser peak power will become higher, making it easier to create high-density arrays of defect regions. Besides, the laser pulse energy used to create the arrays of defect regions is also related to the surface roughness of the wafer.

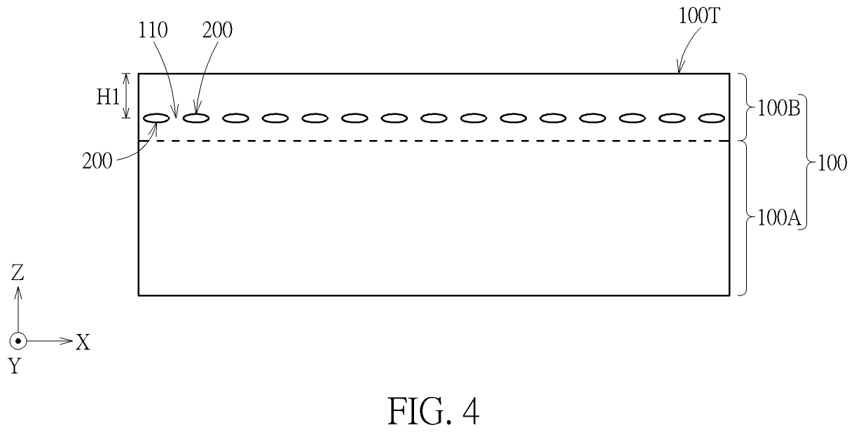

FIG. 4 illustrates a schematic cross-sectional view of an embodiment after performing the first laser process, where a plurality of first defect regions 200 are formed in the surface layer 100B of the wafer 100, and the first defect regions 200 of the present embodiment are all located in the same horizontal plane, such as a plane parallel to the plane defined by the X-axis and Y-axis. In other words, the focal offset distance (parallel to the Z-axis) of the present embodiment is constant. It should be noted that the first defect regions 200 shown in FIG. 4 are not only distributed in the cross-sectional plane shown in FIG. 4 (i.e., the vertical plane parallel to both the X-axis and Z-axis), but also can be distributed in other multiple vertical planes parallel to the X-axis and Z-axis. Therefore, when viewed from above, multiple first defect regions 200 located on the same horizontal plane constitute a first array of defect regions, which has a first depth H1. Specifically, the first depth H1 is the depth of the first array of defect regions below the main surface 100T, and the first depth H1 can be 0.01 μm to 50 μm.

The first defect regions 200 are specific regions modified by laser. Depending on the energy and time duration applied by the laser, the defect density, the number of voids, the number of grain boundaries, and/or the crystal structures of the first defect regions 200 may be different from other regions of the surface layer 100B. In an embodiment of the present invention, the crystal structure and the number of grain boundaries of the defect region 200 are different from the crystal structure and the number of grain boundaries of the surface layer 100B of the wafer 100. For example, the crystal structure of the first defect region 200 is polycrystalline and has more grain boundaries, while the crystal structure of the surface layer 100B outside the first defect region 200 is single-crystal and has almost no grain boundaries. Alternatively, the crystal structure and composition of the first defect region 200 may be different from those of the wafer 100, but not limited thereto. The crystal structure of the first defect region 200 may be different from that of the surface layer 100B of the wafer 100, for example, the crystal structure of the first defect region 200 may be polycrystalline or amorphous, and the crystal structure of the surface layer 100B of the wafer 100 may be single crystal, but not limited thereto.

Depending on the energy applied by the laser and the diameter of the laser spot, the projected area of each first defect region 200 can range from 1 μm² to 104 μm².

Adjacent first defect regions 200 may be separated from each other. In an embodiment, the first defect regions 200 are discontinuously distributed along the X-axis, so that adjacent first defect regions 200 do not directly contact each other. For a specific arrangement where the first defect regions 200 are discontinuously and periodically distributed, untreated regions 110 (for example, the regions not treated by laser) are present between two adjacent first defect regions 200. In this way, the buffering stress effect can be generated by multiple first defect regions 200 and adjacent untreated regions 110 located on the same horizontal plane, which can serve as a stress buffer layer for subsequent epitaxial growth.

In an embodiment, adjacent first defect regions 200 may partially contact each other, so that the first defect regions 200 are continuously distributed along at least one direction. In this embodiment, adjacent first defect regions 200 can be considered as including first sub-defect regions (not shown) and second sub-defect regions (not shown) which are alternately arranged along at least one direction, and the density of lattice defects, lattice constant, crystal planes and/or crystal structure of the first sub-defect region can be different from those of the second sub-defect region. As long as at least one of the sub-defect regions has a periodic distribution, the array constituted by these sub-defect regions can absorb the stress generated at the interface between the wafer 100 and the epitaxial layer.

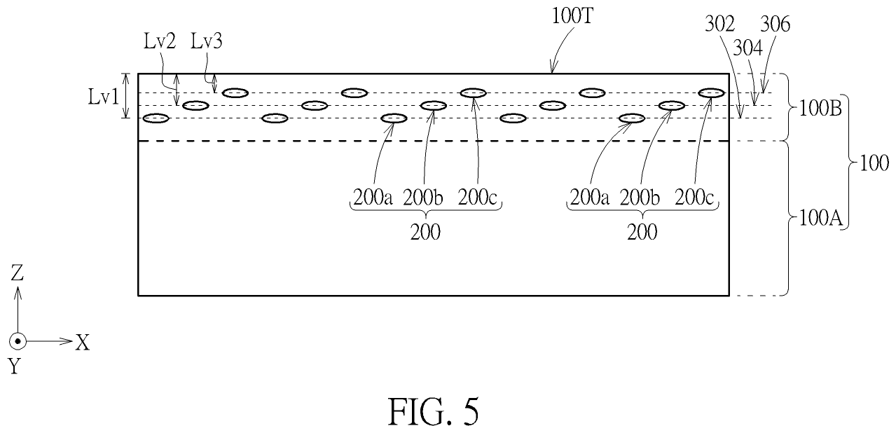

FIG. 5 shows a schematic cross-sectional view of another embodiment of the present invention after performing the first laser process. This embodiment is substantially the same as the first laser process shown in FIG. 4. The difference is that the first laser process of this embodiment includes sequentially and repeatedly performing a first sub-laser process, a second sub-laser process, and a third sub-laser process to generate sub-defect regions 200a, 200b, and 200c, respectively. The first sub-laser process has a first focal offset distance Lv1, the second sub-laser process has a second focal offset distance Lv2, and the third sub-laser process has a third focal offset distance Lv3. The first focal offset distance Lv1 is greater than the second focal offset distance Lv2, the second focal offset distance Lv2 is greater than the third focal offset distance Lv3, and the first focal offset distance Lv1, the second focal offset distance Lv2, and the third focal offset distance Lv3 are located below the main surface 100T within 0.01 μm to 10 μm. In one embodiment, the first focal offset distance Lv1 and the second focal offset distance Lv2 differ by 1 μm to 3 μm, and the second focal offset distance Lv2 and the third focal offset distance Lv3 differ by 1 μm to 3 μm. In addition, other laser parameters of the first sub-laser process, the second sub-laser process, and the third sub-laser process, such as pulse energy, pulse width, and spot size, can be the same or different, depending on the actual requirements.

In FIG. 5, every three sub-defect regions 200a, 200b, and 200c form a regular unit similar to a ladder shape, and this regular unit can extend along the X-axis. Multiple first sub-defect regions 200a can be located at the same depth and distributed on the first horizontal plane 302 parallel to the X-axis and Y-axis, forming the first sub-defect array. Similarly, multiple second sub-defect regions 200b and multiple third sub-defect regions 200c are located at the same depth and are respectively distributed on the second horizontal plane 304 and the third horizontal plane 306 parallel to the X-axis and Y-axis, forming the second sub-defect array and the third sub-defect array. The first depth of the first array of defect regions is the average depth of the first sub-defect array, the second sub-defect array, and the third sub-defect array. In other words, the first depth of the first array of defect regions is the average value of the first focal offset distance Lv1, the second focal offset distance Lv2, and the third focal offset distance Lv3.

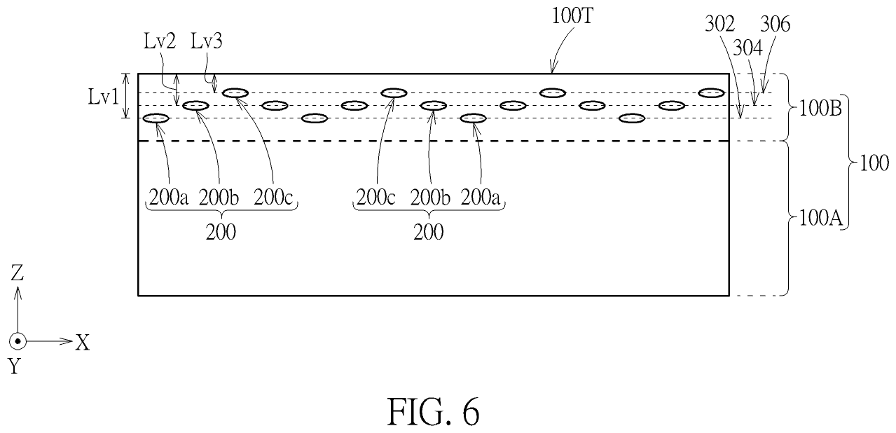

FIG. 6 shows a schematic cross-sectional view of another embodiment of the present invention after performing the first laser process. As shown in FIG. 6, the first laser process in this embodiment is substantially the same as that shown in FIG. 5. The first laser process may also include sequentially and repeatedly performing the first sub-laser process, the second sub-laser process, and the third sub-laser process to generate sub-defect regions 200a, 200b, and 200c, respectively. The first sub-defect region 200a, the second sub-defect region 200b, and the third sub-defect region 200c form a wave-like regular unit, which can be arranged along the X-axis. For example, each of the first sub-defect regions 200a formed by the first sub-laser process may constitute the trough of the wave-like unit, and each of the third sub-defect regions 200c formed by the third sub-laser process may constitute the peak of the wave-like unit.

When the array of defect regions is composed of multiple defect regions located in different depths (for example, step-like regular units or wave-like regular units), the stress at the interface between the wafer and the subsequently formed epitaxial layer can be effectively dispersed, thereby avoiding stress accumulation in the epitaxial layer, or preventing the main surface of the wafer from bending or even breaking.

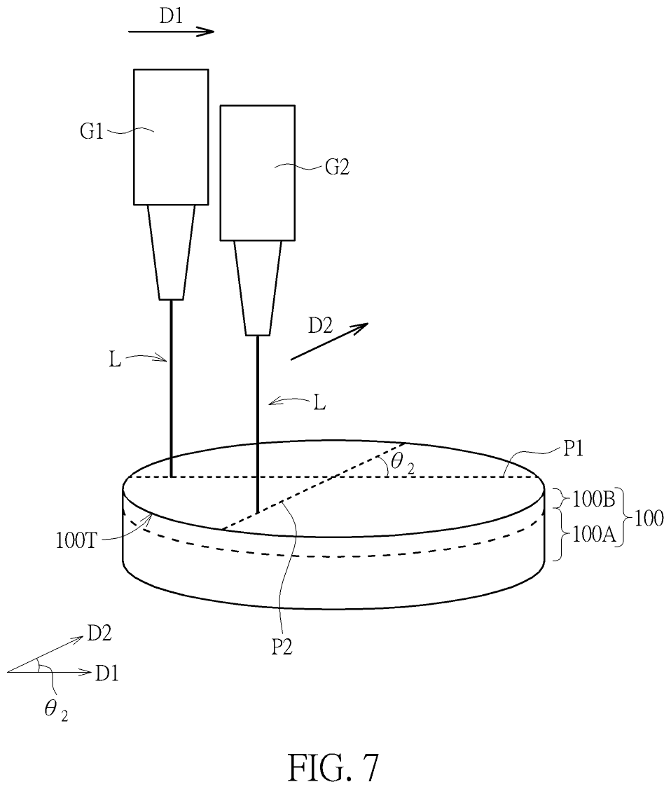

FIG. 7 shows a schematic perspective view of an embodiment of the present invention performing a first laser process and a second laser process. During the first laser process, the laser is irradiated on the surface layer 100B along multiple paths which are parallel to a first direction D1 (e.g., the first scanning path P1 and other parallel paths). During the second laser process, the laser is irradiated on the surface layer 100B along multiple paths parallel to a second direction D2 (e.g., the second scanning path P2 and other parallel paths). In an embodiment, for example, a laser L is generated by a first laser generating device G1 and irradiates the surface layer 100B of the wafer 100, thereby forming multiple first defect regions (not shown) which constitute a first array of defect regions (not shown) on a horizontal plane. The second laser generating device G2 generates a laser L, and the laser L irradiates the surface layer 100B of the wafer 100, thereby forming multiple second defect regions (not shown) which constitute a second array of defect regions (not shown) on a horizontal plane.

In FIG. 7, there is an angle θ2 between the scanning path P1 extending along the first direction D1 and the scanning path P2 extending along the second direction D2, and the angle θ2 can be from 30° to 90°.

Similar to the embodiment in FIG. 4, the second laser process can be performed along the second direction D2, with a focal offset distance of 0.01 μm to 10 μm below the main surface, and the focal offset distance is a fixed value. The focal offset distances of the first laser process and the second laser process can be the same or different from each other.

In an embodiment, the first laser process and the second laser process are performed sequentially and repeatedly. For example, after performing the first laser process along a certain path (e.g., the first scanning path P1), the second laser process is performed along another path (e.g., the second scanning path P2), and the above processes are repeatedly performed.

Similar to the embodiment in FIG. 5, the second laser process may include sequentially and repeatedly performed a fourth sub-laser process, a fifth sub-laser process, and a sixth sub-laser process. The fourth sub-laser process has a fourth focal offset distance, the fifth sub-laser process has a fifth focal offset distance, and the sixth sub-laser process has a sixth focal offset distance. The fourth focal offset distance is greater than the fifth focal offset distance, the fifth focal offset distance is greater than the sixth focal offset distance, and the fourth focal offset distance, fifth focal offset distance, and sixth focal offset distance are located at 0.01 μm to 10 μm below the main surface 100T. Correspondingly formed fourth sub-defect regions form a fourth sub-defect array on a horizontal plane, correspondingly formed fifth sub-defect regions form a fifth sub-defect array on a horizontal plane, and correspondingly formed sixth sub-defect regions form a sixth sub-defect array on a horizontal plane. The fourth sub-defect array, fifth sub-defect array, and sixth sub-defect array may together constitute the second array of defect regions. Any one of the first focal offset distance, second focal offset distance, and third focal offset distance of the first laser process is different from any one of the fourth focal offset distance, fifth focal offset distance, and sixth focal offset distance of the second laser process.

In FIG. 7, in one embodiment, the first laser process and the second laser process can be performed simultaneously, followed by an optional annealing treatment. In this way, the main surface 100T or surface layer 100B of the wafer 100 is irradiated with a laser to change the crystallinity of the surface layer 100B. In another embodiment, the first laser process is performed first, and then an optional first annealing treatment is performed to eliminate the stress generated by the laser process. Afterwards, the second laser process is performed, followed by performing an optional second annealing treatment to prevent stress accumulation. It should be noted that although a laser process with a specific wavelength can penetrate the wafer, it inevitably causes slight lattice displacement (e.g., less than 5 Å) along the penetration path. Since the first annealing treatment is performed before the second laser process, it ensures that the slightly displaced lattice is repaired to the lattice state before the laser process, and thus improves the accuracy of the second laser process.

In an embodiment, the first laser process and the second laser process have the same pulse energy, resulting in the first defect regions and second defect regions having substantially the same or similar defect density, number of voids, number of grain boundaries, and/or crystal structure. Moreover, depending on the actual requirements, the laser parameters of the first laser process and second laser process, such as pulse energy, pulse width, and light spot size, can be the same or different.

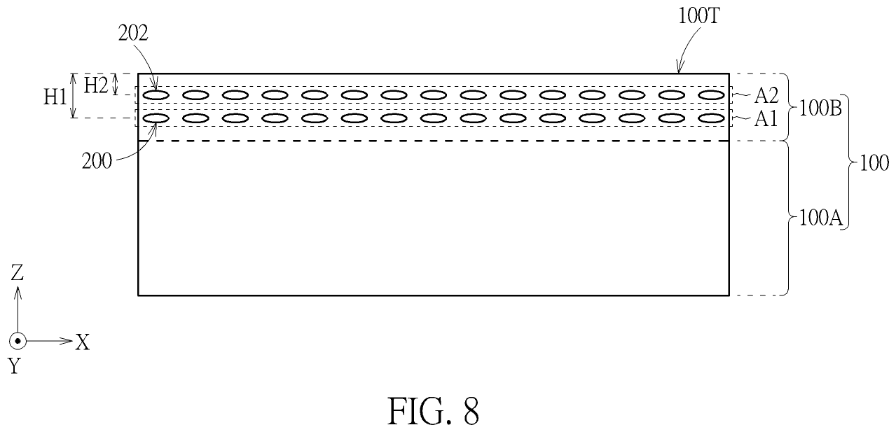

FIG. 8 illustrates a cross-sectional view of an embodiment of the present invention after performing the first laser process and the second laser process, where multiple first defect regions 200 are present in the surface layer 100B of the wafer 100. Multiple first defect regions 200 are distributed on a horizontal plane and constitute a first array A1 of defect regions. The first array A1 of defect regions has a first depth H1. The surface layer 100B of the wafer 100 also has multiple second defect regions 202. Multiple second defect regions 202 are distributed on another horizontal plane and constitute a second array A2 of defect regions. The second array A2 of defect regions has a second depth H2. In this embodiment, the first depth H1 is different from the second depth H2, and the first depth H1 is greater than the second depth H2. It should be noted that the first defect regions 200 and the second defect regions 202 shown in FIG. 8 are not only distributed in the cross-sectional plane shown in FIG. 8 (i.e., a vertical plane parallel to the X-axis and Z-axis), but the first defect regions 200 and the second defect regions 202 can also be distributed in other multiple vertical planes parallel to the X-axis and Z-axis.

In another embodiment, the first depth H1 of the first array A1 of defect regions can be the same as the second depth H2 of the second array A2 of defect regions. None of the first defect regions 200 of the first array A1 contact any second defect region 202 of the second array A2, and a second defect region 202 can be present between any two adjacent first defect regions 200.

It should be noted that since the first direction of the first laser process and the second direction of the second laser process are not parallel to each other, and the scanning pitch of the laser respectively generated by the first laser generating device and the second laser generating device can be adjusted according to the desired layout of the defect array. Thus, when the wafer 100 is viewed from above, some of the first defect regions 200 and some of the second defect regions 202 can be non-overlapping.

Similarly, according to different requirements, the wafer processing method of the present invention also includes performing a third laser process along a third direction to form multiple third defect regions in the surface layer 100B, which constitute a third array of defect regions on a certain horizontal plane. In this way, the surface layer 100B of the wafer 100 simultaneously has the first array of defect regions, the second array of defect regions, and the third array of defect regions.

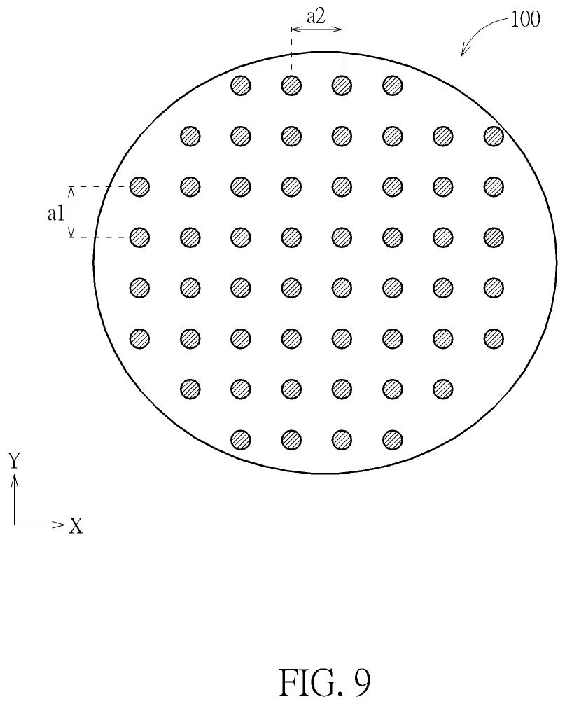

FIG. 9 illustrates a schematic top view of a defect array according to an embodiment of the present invention, where the defect array has a unit length a1 and a unit width a2. The unit length a1 is parallel to the Y-axis, and the unit width a2 is parallel to the X-axis. In this embodiment, the unit length a1 and the unit width a2 are the same, so the defect array in FIG. 9 can be considered as being constituted by multiple square units. In another embodiment, the unit length a1 is greater than the unit width a2, so the defect array can be considered as being constituted by multiple rectangular units. In yet another embodiment, the unit length a1 has an angle of 30° to 60° with the Y-axis, and the unit width a2 is parallel to the X-axis, so the defect array can be considered as being constituted by multiple parallelogram units.

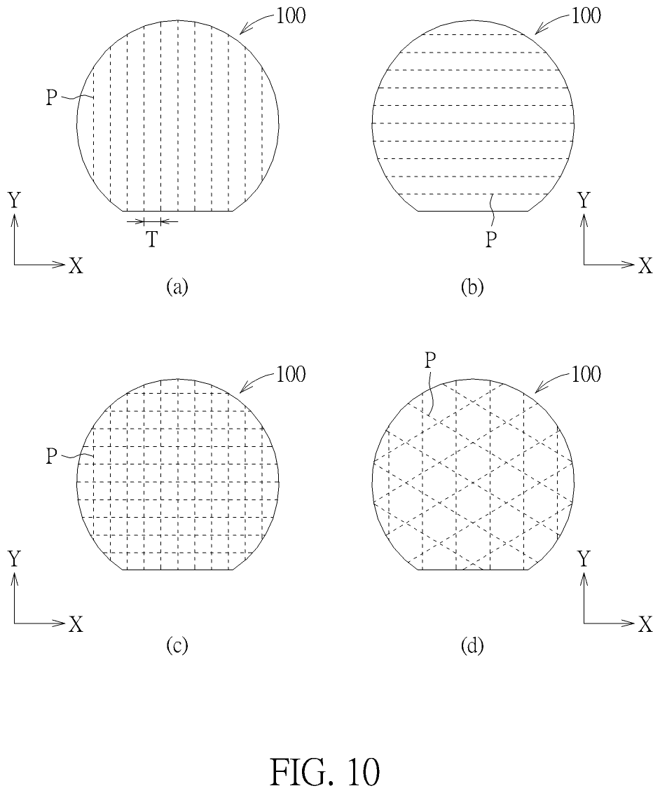

FIG. 10 shows schematic top views of laser scanning paths for different embodiments of the present invention during laser processing. The scanning paths P for two or more laser processes of the present invention may be the same or different. As shown in a layout (a), the scanning path P can be linear along the Y-axis, and adjacent scanning paths P having a scanning width T. The laser spot width can be 2 μm to 100 μm. The laser scanning pitch is the interval distance between two adjacent laser spots generated by the laser generating device. In one embodiment, the scanning pitch is 1 μm to 100 μm. As shown in a layout (b), the scanning path P can be linear along the X-axis. As shown in a layout (c), in the case of performing two or more laser processes, the scanning path P of the first laser process can be linear along the Y-axis, and the subsequent laser process can be linear along the X-axis, or the first laser process can be linear along the X-axis and the subsequent laser process can be linear along the Y-axis. As shown in a layout (d), in the case of performing three or more laser processes, the scanning path P of the first laser process can be linear along the Y-axis, and the subsequent two laser processes can be sequentially performed along two other different scanning directions.

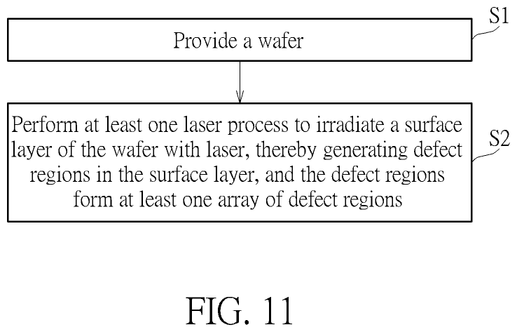

FIG. 11 shows a flowchart of a method for a wafer treatment according to an embodiment of the present invention. In FIG. 11, the method for the wafer treatment may include steps S1 and S2. As shown in FIG. 11, in step S1, a wafer is provided. In step S2, at least one laser process is performed to irradiate the entire surface layer with a laser, thereby generating multiple defect regions in the surface layer. The multiple defect regions can constitute at least one array of defect regions. According to different requirements, after performing step S2, the method for the wafer treatment further includes performing annealing treatment to irradiate the main surface or surface layer of the wafer with a laser, thereby changing the crystallinity of the surface layer.

According to the above-described embodiment of the present invention, a laser process is used to form multiple defect regions in the surface layer of a wafer, thereby creating at least one array of defect regions. When a subsequent epitaxial layer is grown on the main surface of the wafer, the array of defect regions is beneficial for buffering or absorbing the stress caused by lattice constant mismatch or thermal expansion coefficient mismatch between the wafer and the epitaxial layer. Compared to the conventional method in which a buffer epitaxial layer is grown on the wafer so as to solve the aforementioned problem, the present invention has the advantages of simpler steps and lower costs. Furthermore, as there is no need to grow an additional buffer epitaxial layer on the wafer, the thickness of the corresponding semiconductor device can be reduced, and even the degree of wafer thinning performed subsequently can be decreased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for a wafer treatment, comprising:
providing a wafer, wherein the wafer comprises a main surface, a surface layer and a base layer, wherein the surface layer is located between the main surface and the base layer; and
performing at least one laser process to irradiate the surface layer with laser, thereby generating a plurality of defect regions in the surface layer, and the defect regions form at least one array of defect regions.

2. The method for a wafer treatment of claim 1, wherein performing the at least one laser process comprises:
performing a first laser process to irradiate the surface layer with laser so that the plurality of defect regions are arranged along a first direction, and the focal offset distance of the laser is in a range of 0.01 μm to 50 μm below the main surface, and the focal offset distance is constant.

3. The method for a wafer treatment of claim 1, wherein performing the at least one laser process comprises:
performing a first laser process to irradiate the surface layer with laser so that the plurality of defect regions are arranged along a first direction, wherein performing the first laser process comprises:
sequentially and repeatedly performing a first sub-laser process, a second sub-laser process and a third sub-laser process, wherein the first sub-laser process has a first focal offset distance, the second sub-laser process has a second focal offset distance and the third sub-laser process has a third focal offset distance, and the first focal offset distance, the second focal offset distance and the third focal offset distance are located below the main surface from 0.01 μm to 50 μm, wherein the first focal offset distance is greater than the first focal offset distance.

4. The method for a wafer treatment of claim 1, wherein performing the at least one laser process comprises:
performing a first laser process to irradiate the surface layer with laser so that some of the plurality of defect regions are arranged along a first direction, wherein the focal offset distance of the laser is 0.01 μm to 10 μm below the main surface, and the focal offset distance is constant; and
performing a second laser process to irradiate the surface layer with laser to so that others of the plurality of defect regions are arranged along a second direction, wherein the focal offset distance of the laser is 0.01 μm to 10 μm below the main surface, and the focal offset distance is constant, wherein,
an included angle is between the first direction and the second direction, and the included angle is 30 to 90 degrees, and the focal offset distance of the first laser process and the focal offset distance of the second laser process are the same or different from each other,
the first laser process and the second laser process are sequentially and repeatedly performed.

5. The method for a wafer treatment of claim 1, wherein performing the at least one laser process comprises:
performing a first laser process to irradiate the surface layer with laser, so that some of the plurality of defect regions are arranged along a first direction, wherein performing the first laser process comprises:
sequentially and repeatedly performing a first sub-laser process, a second sub-laser process and a third sub-laser process, wherein the first sub-laser process has a first focal offset distance, the second sub-laser process has a second focal offset distance and the third sub-laser process has a third focal offset distance, and the first focal offset distance, the second focal offset distance and the third focal offset distance are 0.01 μm to 10 μm below the main surface; and
performing a second laser process to irradiate the surface layer with laser so that others of the plurality of defect regions are arranged along a second direction, wherein performing the second laser process comprises:
sequentially and repeatedly performing a fourth sub-laser process, a fifth sub-laser process and a sixth sub-laser process, wherein the fourth sub-laser process has a fourth focal offset distance, the fifth sub-laser process has a fifth focal offset distance and the sixth sub-laser process has a sixth focal offset distance, and the fourth focal offset distance, the fifth focal offset distance and the sixth focal offset distance are 0.01 μm to 50 μm below the main surface, wherein,
an included angle is between the first direction and the second direction, and the included angle is 30 degrees to 90 degrees,
the first focal offset distance is greater than the second focal offset distance, the second focal offset distance is greater than the third focal offset distance, the fourth focal offset distance is greater than the fifth focal offset distance, and the fifth focal offset distance is greater than the sixth focal offset distance, and any one of the first focal offset distance, the second focal offset distance and the third focal offset distance is different from any one of the fourth focal offset distance, the fifth focal offset distance and the sixth focal offset distance.

6. The method for a wafer treatment of claim 5, wherein the time of performing the first laser process is the same as the time of performing the second laser process, or the time of performing the first laser process is earlier than the time of performing the second laser process.

7. The method for a wafer treatment of claim 4, wherein the first laser process and the second laser process have a same pulse energy.

8. The method for a wafer treatment of claim 1, wherein the at least one array of defect regions comprises:
a first array of defect regions located at a first depth below the main surface; and
a second array of defect regions located at a second depth below the main surface, wherein,
the first depth is different from the second depth.

9. The method for a wafer treatment of claim 1, wherein, during performing at least one laser process, scanning path of the laser is linear, scanning pitch of the laser is 1 μm to 100 μm, and scanning width of the laser is 2 μm to 100 μm.

10. The method for a wafer treatment of claim 1, further comprising:
performing an annealing treatment to irradiate the main surface or the surface layer of the wafer with laser, and to change the crystallinity of the surface layer.

11. The method for a wafer treatment of claim 5, wherein the first laser process and the second laser process have a same pulse energy.
